(19) United States
(12) Patent Application Publication
(10) Pub. No.: US 2013/0268224 A1
(43) Pub. Date: Oct. 10, 2013

(54) METHOD FOR MEASURING THE COINCIDENCE COUNT RATE, USING A TIME-TO-DIGITAL CONVERSION AND AN EXTENDIBLE DEAD TIME METHOD WITH MEASUREMENT OF THE LIVE TIME

(71) Applicant: Christophe Bobin, Orsay (FR)

(72) Inventor: Christophe Bobin, Orsay (FR)

(73) Assignee: COMMISSARIAT A L'ENERGIE ATOMIQUE ET AUX ENERGIES ALTERNATIVES, Paris (FR)

(21) Appl. No.: 13/995,460

(22) PCT Filed: Dec. 19, 2011
(86) PCT No.: PCT/EP11/73213

§ 371 Date: Jun. 18, 2013

(30) Foreign Application Priority Data
Dec. 20, 2010 (FR) 10 60771

(51) Int. Cl. G01R 29/027

(52) U.S. Cl. CPC G01R 29/0273
USPC 702/79

(57) ABSTRACT

A method for measuring the coincidence count rate, using a time-to-digital conversion and an extendible dead time method with measurement of the live time. The count rate of coincident events between radiation detectors operating in parallel is measured, the time fluctuations of the coincident events are converted into digital form, and the extendible dead time method is used with measurement of the live time to eliminate all the other correlated events which may occur in a given detector. The time distributions of the time intervals separating the pulses are recorded, and the count rate of the coincident events is measured using recorded time distributions.

### TECHNICAL FIELD

The present invention relates to a method for measuring the count rate of coincident events between multiple radiation detectors operating in parallel.

The term “radiation” signifies photons or particles.

Measurement is made by recording the distribution of time intervals which are defined by the duration between a start signal, provided by a measuring channel, and a stop signal, from another measuring channel. Depending on the number of channels used there may be multiple stop signals, leading to measurement of multiple coincidences, for example double coincidences or triple coincidences.

We mention at the present juncture that, according to one aspect of the invention, a time-to-digital conversion, more specifically a conversion in digital form of the recorded time intervals, is combined with a protection against sequences of start and stop signals which may be the cause of distorted time measurements with the known measuring techniques.

In particular, the aim is to obtain a time-to-digital conversion which is suitable for the random distributions of the arrival times of the signals delivered by the radiation detectors.

According to other aspects of the invention, the abovementioned protection uses an extendible dead time method; this dead time is common to the different channels; it is built from the start and stop signals; this extendible dead time method is combined with a real-time measurement of the live time.

Application of the live time method enables the effective count periods, used to determine the coincidence rate between the different channels of the radiation detection system, to be measured.

On the subject of the extendible dead time method with measurement of live time, reference will be made to the following documents:

[1] J. Bouchard, “MTR2: a discriminator and dead-time module used in counting systems”, Applied Radiation and Isotopes 52 (2000) 441-446;

[2] EP 0 574 287, “Dead time circuit of the extendible type”, invention of J. Bouchard.

The present invention applies notably to nuclear instruments which implement measurement of coincidences between radiation detectors.

In the specific case of metrology of radioactivity, the invention for example enables the activity of a radionuclide to be determined.

### STATE OF THE PRIOR ART

By definition, the expression “dead time” designates a period of paralysis of a measuring system. This period follows the detection of a pulse in the system. During this period no new pulse may be processed correctly for the acquisition of data, such as a count rate or an amplitude, for example.

The cause of the paralysis depends on the system used; it may be a saturation of pulses or of correlated after-pulses.

In what follows, the expression “extendible dead time method” designates a method enabling the paralyses of the detection system in question to be managed. It consists in preventing, for a predefined period, any processing of a pulse in order to extract an item of information from it, following the detection of this pulse.

Unlike a non-extendible dead time method, every new incoming signal during this period is used only to extend it by the same predefined duration. The system becomes free or active once again when no new pulse has been detected.

The live time method consists in measuring the total of the live times between the dead time periods by counting the pulses of a clock. It may then be considered that the real time of a measurement is sampled.

In the field of nuclear instrumentation it is common to implement a count method consisting in measuring the rate of coincidences between two, or more than two, radiation detectors operating in parallel.

Two techniques are generally applied to count coincidences.

The first is based on the use of a logical circuit which produces a coincidence resolution time for each channel. The coincidences are metered by constructing an overlap period between the logical signals.

The second consists in measuring time intervals between the channels so as to obtain the record of the time distribution. The time interval measuring sequence starts with a start signal which is provided by a channel. And the time intervals are measured using the stop signals which appear in the other channels.

The second method enables the information given by the time fluctuations of the detection system for counting the coincidences to be retained. From the record of histograms of durations of occurrence between the channels, off line processing enables the delay and the length of the coincidence resolution time to be adjusted such that they are suitable for the detection system.

In an analog device recording a time interval requires two steps: the time interval between the start and stop signals is firstly converted into the form of an amplitude, and the latter is then used by a multichannel analyser for recording the time distribution.

The disadvantage of such a method is the introduction of a period of paralysis. This is due in particular to the amplitude conversion method, which requires a capacitor-charging period. The multichannel analyser may also contribute significantly to the paralysis of the measuring system.

Depending on the count rates and the detection system used, this paralysis of the device leads to a distortion in the measurement of the coincidence rates. On this subject, reference will be made, for example, to the following document:

[3] Time-to-amplitude converters and time calibrator, ORTEC®, 17 Dec. 2009.

The change to digital technology enables the time distribution to be recorded directly from measurements of the durations between the start and stop signals. The paralysis found in the analog device is consequently significantly reduced.

In a simple version a time-to-digital converter makes the time measurement from the count of the pulses of a clock, the frequency of which defines the optimum time resolution of the device. More sophisticated systems enable this resolution to be improved through the use of interpolation methods or of the Vernier method.

The known systems intended to measure time intervals, have a disadvantage: with these systems the problem of paralysis does not take into account the detection means which are associated with them.

As an example, there are analytical approaches which enable the count losses in the case of the analog devices to be corrected. However, the corrections are then based on the use of a non-extendible dead time method. This method is unsuitable for the paralyses caused by sequences of random pulses, leading to intermingled start and stop signals.

This problem is potentially significant when, in the radiation detector, a given event generates after-pulses correlated with the input of a single channel.

This disadvantage cannot be disregarded in the field of metrology of radioactivity. It is stipulated that after-pulses may also be due to metastable states characteristic of certain radionuclides.

### DESCRIPTION OF THE INVENTION

One aim of the invention is to remedy this disadvantage.

To accomplish this, according to one aspect of the invention, it is proposed to measure the count rate of the coincidences between different detection channels operating in parallel, by means of a digital system operating in real time.

An algorithm is implemented in this system. This algorithm combines a time-to-digital conversion, intended to measure time intervals, with a transposition of an extendible dead time method. This dead time is common to all the channels. On this subject, reference will be made to the following document:

[4] J. Bouchard et al., “MAC3: an electronic module for the processing of pulses delivered by a three photomultiplier liquid scintillation counting system”, Applied radiation and isotopes, 52 (2000), pp. 669-672.

The algorithm is preferably implemented in a programmable component of the FPGA (Field-Programmable Gate Array) type, with a view to real-time processing.

The actual measuring time is determined by means of a transposition of the live time method. To this end, sampling is accomplished by means of the clock contained in the programmable component.

It should be noted that a transposition in digital form of the module described in document [4], in the case of a measurement of coincidences using an overlap time, is known by the following document, to which reference will be made:

[5] C. Bobin et al., “First results in the development of an on-line digital counting platform dedicated to primary measurements”, Applied radiation and isotopes, 68 (2010), pp. 1519-1522.

One feature of the invention is that it includes no particular channel dedicated to starting the measurement of the time intervals: the start of a measurement is initiated by any one of the detectors. The invention may consequently be adapted to a symmetrical detection system, for example a system intended for application of the TDCR (Triple to Double Coincidence Ratio) method.

When the measurement has been initiated by one of the channels the algorithm manages the input times of the pulses in the other channels to establish time histograms of the multiple coincidences between the channels (double coincidences, triple coincidences, etc.).

According to the extendible dead time method, the after-pulses correlated in the different channels are used to extend the dead time.

The acquired element of information, namely the histograms for the multiple coincidences between the channels, is recorded in an acquisition computer; the measured live time is recorded in it.

Reference will be made to the following document:

[6] WO 2010/125062, “Method for measuring the count rate of pulses, using a method of the extendible dead time type with measurement of the live time”, invention of B. Censier.

There are several differences between the various aspects of the present invention and the method described in this document [6].

Firstly, in the present invention an algorithm is applied in real time to a detection system having at least two channels, whereas a single channel is considered in the document. And measurement of the live time is applied directly by sampling periods outside the dead time using a clock.

The dates of occurrence of the pulses are not therefore recorded in an acquisition computer with a view to post-processing of the count and of the live time, whereas the method described in the document uses offline processing.

In addition, one aim of the present invention is measurement of a coincidence count rate between several detectors.

Moreover, in terms of paralysis of the detection system, the present invention essentially resolves a problem of processing of the correlated after-pulses, i.e. after-pulses which are generated in the detectors used, or which may result from metastable states of certain radionuclides. This is the reason why the dead time is common to the different channels of the measuring system. It does not merely relate to periods of paralysis caused by the discrimination period.

In terms of the algorithm, the invention is closer to the almost-direct digital transposition of the MAC3 analog module which has previously been accomplished (see documents [4] and [5]).

But a major difference between the present invention and that which has previously been accomplished lies in the measurement of the coincidences: in the invention they are measured using the record of the time distributions.

In precise terms, the object of the present invention is a method for measuring the count rate of coincident events between N radiation detectors operating in parallel, and associated respectively with N detection channels, where N is an integer equal to at least 2, and where each detector is able to send an electric pulse over the detection channel with which it is associated when an event occurs in this detector, in which:

the time fluctuations of the coincident events are converted into digital form, and

the extendible dead time method is used with measurement of the live time to eliminate all the other correlated events which may occur within a given detector,

characterised in that:

the time distributions of the time intervals separating the pulses are recorded, and

the count rate of the coincident events is measured using the recorded time distributions.

The live time is preferably measured in real time.

In addition the dead time is preferably common to the N detection channels.

According to one preferred embodiment of the invention:

measurement of the count rate is initiated by one of the N detection channels when an event occurs in the detector associated with it, and

when the measurement is initiated an algorithm is implemented which establishes time histograms for the multiple coincidences between the N detection channels, i.e. for the coincident events between P detectors from among the N radiation detectors, where P spans all the integers ranging from 2 to N, from the input times of the pulses in the N−1 other detection channels.

In the present invention the detectors can be identical to one another.

In this case, according to one particular embodiment of the invention, N is equal to 3, the detectors are photomultipliers and the method is used to implement the triple to double coincidence ratio method.

But it is also possible for the detectors not to be identical to one another.

In this case, according to another particular embodiment of the invention, N is equal to 2, the detectors are respectively a gamma photon detector and an electron detector, and the method is used to implement the beta-gamma coincidence method.

### BRIEF DESCRIPTION OF THE ILLUSTRATIONS

The present invention will be better understood on reading the description of example embodiments given below, purely as an indication and in no sense restrictively, making reference to the appended illustrations in which:

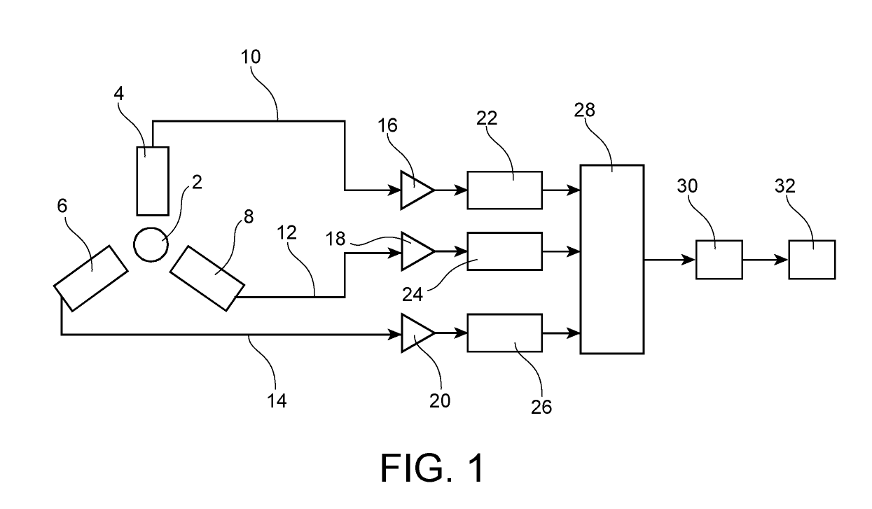

FIG. 1 is a schematic view of a measuring sequence which is intended to determine the activity of a radionuclide by the TDCR method, and in which an example of the method which is one object of the invention is implemented,

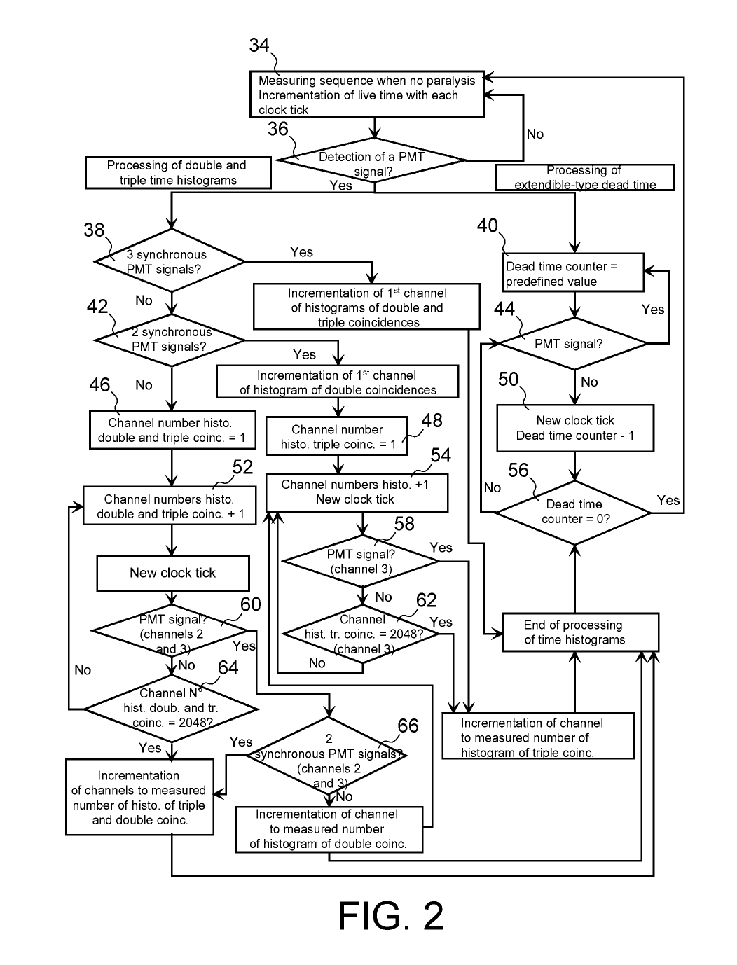

FIG. 2 is a flow chart of an algorithm which is used in this example, and which processes in parallel measurements and management of the extendible dead time, and

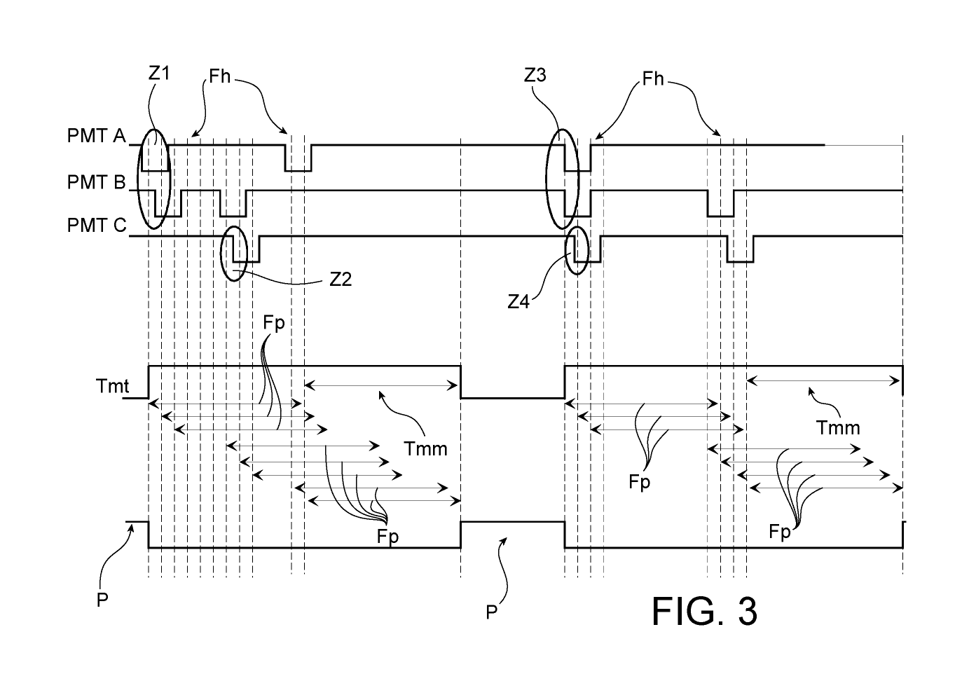

FIG. 3 is a timing diagram relative to this algorithm.

### DETAILED DESCRIPTION OF PARTICULAR EMBODIMENTS

The example which will be described is relative to an application of the invention to the TDCR method which is commonly used for measuring an activity by liquid scintillation counting.

Use of this method enables the advantages of the invention to be highlighted if the arrival of the start and stop signals is random due to the existence of correlated after-pulses which may lead to confused periods in the measurement of the time intervals.

The two most important phenomena causing after-pulses are:

light emission in the course of liquid scintillation which results from various physical-chemical mechanisms leading to a spreading of the time distribution of the emitted photons, and

ionisation of the residual gas present in the photomultipliers used to implement the TDCR method.

The measuring sequence, to which we shall return below, includes three counting channels, or detection channels, which are identical; and each of these channels starts with a photomultiplier.

Detection is accomplished symmetrically such that each of the channels is able to initiate a sequence of measuring and extendible dead time. There is therefore no channel specifically dedicated to initiating a process of measuring time intervals.

When the measuring period has been initiated by a first electrical pulse which has been sent to one of the three channels, the other two channels are used to implement time histograms corresponding to second and third pulses (for counting the double and triple coincidences).

In the case of a measurement by the TDCR method, data is recorded in an acquisition computer in the form of two time histograms, corresponding to the arrival times of the second and third pulses. Recording of the total live time (total of the periods outside the dead time) enables the double and triple coincidence rates between the channels to be calculated.

It should be recalled that, in accordance with the invention, coincident events are measured, but only between different detectors. There may be such events in a given detector, but they give no information concerning the measurement. Protection is afforded against these correlated events in a given detector using the extendible dead time method, with measurement of the live time: account is taken only of the first event in a detector, but not of other subsequent events in this detector during the dead time period.

Purely for information, and in no sense restrictively, a device using the TDCR measuring method was produced using a commercially available digital card, namely an Altera® development kit, fitted with a Stratix® III FPGA circuit.

And, in this logic circuit a program was implemented enabling time histograms to be recorded with a sampling depth which was set at 2048 channels.

In addition a sampling frequency equal to 125 MHz was chosen, leading to a minimum time resolution of 8 ns.

To implement the histograms the time per channel is defined according to a multiple of the minimum time resolution.

This increase of the time dynamics is accomplished, however, at the cost of a loss of resolution; but the programming flexibility of the FPGA circuit enables this loss to be remedied by increasing the sampling depth.

The total measuring time and the minimum dead time are defined by the user according to a number of clock ticks.

And the link between the digital portion of the measuring sequence and the acquisition computer is made by means of an Ethernet connection.

FIG. 1 is a schematic view of the measuring sequence in which an example of the method forming the object of the invention is implemented.

In this measuring sequence the light is detected in an optical chamber (not represented). In this optical chamber a flask 2 containing a blend of a liquid scintillator and of a radioactive source, the activity of which it is sought to determine by the TDCR method, are introduced.

To detect the scintillation light, three photomultipliers 4, 6 and 8 are used, which are positioned symmetrically around flask 2, at 120° relative to one another.

Following a radioactive decay an ionising radiation is emitted. This leads to energy deposition in the liquid scintillator. This leads to the emission of light photons which are distributed at random between the three photomultipliers.

In the measuring sequence each photomultiplier converts one incident light photon into a photoelectron. This conversion is accomplished through a photocathode positioned at the input of the photomultiplier, and depends on the quantum yield of the photocathode.

In addition, the photomultiplier includes a sequence of dynodes. A process of multiplication of the photoelectrons produced in the photocathode takes place in the photomultiplier. By this means a current is obtained which is sufficiently high for it to be transformed into a voltage pulse which can be used by a fast amplifier.

This pulse is sent to a detection channel which connects the photomultiplier to the fast amplifier. In FIG. 1 detection channels 10, 12 and 14 have been represented, which respectively connect photomultipliers 4, 6 and 8 to fast amplifiers 16, 18 and 20.

These amplifiers 16, 18 and 20 are associated respectively with analog devices 22, 24 and 26, namely CFDs, i.e. constant fraction discriminators. The signal delivered by each amplifier powers the CFD associated with it.

The measuring sequence also includes a digital device 28 which is constituted by an FPGA in the described example. In this FPGA the time-to-digital conversion and the protection mentioned above, and to which we shall return subsequently, have been programmed.

All the CFDs allow a change from the analog portion of the detection system to time-to-digital digital conversion device 28. Each CFD produces a logic signal which can be used directly by this device 28, and has the advantage that it reduces the time fluctuations generally found in the case of conventional threshold discrimination.

More specifically, the three CFDs, which are fitted respectively to the detection channels, supply logic pulses. These pulses reflect the start and stop signals arriving at the input of digital device 28.

The measuring sequence also includes an acquisition computer 30 which processes the time histograms supplied by digital device 28 and determines the sought count rates. In the described example this computer is connected to digital device 28 by an Ethernet link. In addition, computer 30 is fitted with a device 32 for displaying the measurement results.

We shall now consider the algorithm represented in FIG. 2. This algorithm is used in FPGA 28 forming part of the measuring sequence represented in FIG. 1, and processes in parallel the time-to-digital conversion and management of the extendible dead time.

We shall also consider the timing diagram represented in FIG. 3, which relates to this algorithm.

The algorithm is as represented in FIG. 2. Several elements of it are stipulated simply below, to clarify certain abbreviations.

At 34 the initial state is one in which the measuring sequence is not paralysed; the live time is incremented with each clock tick. At 36, it is asked whether a signal is detected from any one of the photomultipliers (shortened to: PMT). At 38, it is asked whether or not there are three synchronous signals respectively from the three PMTs. At 40 the dead time counter is set to a predefined value.

At 42, it is asked whether or not two PMTs from among the three PMTs are supplying synchronous signals. At 44, it is asked whether or not one of the PMTs is supplying a signal. At 46 the channel number of the histogram of the double coincidences is equal to 1 and the channel number of the histogram of the triple coincidences is equal to 1. At 48 the channel number of the histogram of the triple coincidences is equal to 1.

At 50, when a new clock tick occurs, the dead time counter is decremented by 1. At 52 the channel number of the histogram of the double coincidences is increased by 1 and the channel number of the histogram of the triple coincidences is increased by 1. At 54 the channel number of the histogram of the triple coincidences is increased by 1 and there is a new clock tick. At 56, it is asked whether or not the dead time counter is set to 0.

At 58, it is asked whether or not there is a PMT signal in channel n° 3. With this regard, the following clarifications are made:

channel n° 1 is the first channel in which a signal from the corresponding PMT is detected, namely one of PMTs A, B and C with the references of FIG. 3;

PMT A is one of the three PMTs of FIG. 1, PMT B is one of the two other PMTs of FIG. 1 and PMT C is the last of the three PMTs of FIG. 1; and

channel n° 2 (respectively n° 3) is the second (respectively the third) channel in which a signal from the PMT corresponding to this second (respectively third) channel is detected.

At 60, it is asked whether or not a PMT signal is detected in each of channels n° 2 and 3. At 62, it is asked whether or not the channel of the histogram of the triple coincidences is equal to 2048 (in the case of channel n° 3), where 2048 is the largest channel in the example in question.

At 64, it is asked whether or not the channel of the histogram of the double coincidences is equal to 2048, and it is asked whether or not the channel of the histogram of the triple coincidences is equal to 2048 (in the case of channels n° 2and 3). At 66, it is asked whether or not the signals from the PMTs corresponding respectively to channels n° 2 and 3 are synchronous.

Let us now consider the timing diagram of FIG. 3.

The first three lines of this timing diagram concern PMTs A, B and C which have previously been mentioned. Arrows Fh designate dotted lines representing the clock signals of which the period is equal to 8 ns in the example in question. Arrows Fp represent the prolongation of the dead time. The line noted Tmt is the total dead time. Tmm designates the minimum dead time. P designates the live time's measuring period. The slots which can be seen in the Tmt line reflect the dead time periods obtained by successive extensions of minimum dead time Tmm.

Zone Z1 corresponds:

to the initiation of the measurement by PMT A which then supplies a first pulse,

to a second pulse, supplied by PMT B, with a delay of 1 clock tick, and

to the incrementation of the 2^{nd} channel of the histogram of the double coincidences.

Zone Z2 corresponds:

to a third pulse, supplied by PMT C, with a delay of 7 clock ticks, and

to the incrementation of the 8^{th} channel of the histogram of the triple coincidences.

Zone Z3 corresponds:

to the initiation of the measurement by PMT A and PMT B, and

to the incrementation of the 1^{st} channel of the histogram of the double coincidences.

Zone Z4 corresponds:

to a third pulse, supplied by PMT C, with a delay of 1 clock tick, and

to the incrementation of the 2^{nd} channel of the histogram of the triple coincidences.

We now return to the algorithm of FIG. 2.

Implementation of this algorithm in FPGA circuit 28 (FIG. 1) is based on a synchronous management of the logic pulses delivered by CFD modules 16, 18 and 20.

By this means the time resolution is limited by the sampling frequency in the FPGA (which constitutes a digital device). However, this implementation has no disadvantages for the accuracy of the measurement of the coincidences between the channels.

During the acquisition time defined by the user the FPGA may initiate a time measurement phase only if it is previously in the live time, i.e. outside the dead time.

The time measuring sequence and the dead time are described in the flow chart of FIG. 2 and the timing diagram of FIG. 3. They are initiated when a clock pulse is synchronous with at least one logic signal from the three CFD modules.

It should be noted that the processing of the histograms of the time intervals and of the extendible-type dead time is implemented using two processes which are executed in parallel from the same logic signals.

The minimum dead time is predefined by the user. It must always be greater than the temporal dynamics of the histograms, dynamics which define the maximum measurable time interval.

Once the sequence has been initiated the algorithm examines the arrival of a logic signal in the channels which have not initiated the time-measurements phase. The duration between the arrivals of the first and second pulses is expressed as a number of clock ticks. This number is used to increment in real time the corresponding channel in the time histogram of the double coincidences.

When two logic signals from two different channels are detected synchronously by a clock pulse the measuring phase is initiated and the first channel of the histogram of the double coincidences is incremented.

In the special case in which no second pulse is detected during the period corresponding to the coding depth of the time histogram (minimum value in the example described: 2047×8 ns=16.376 μs), the last channel is incremented with the aim of keeping the information of a dead time period which has been initiated.

When two logic signals from two different channels have already been detected during the current sequence (whether or not simultaneously), the algorithm examines the arrival of a logic signal in the third channel. The duration between the arrivals of the first and third pulses is expressed as a number of clock ticks. This number is used to increment in real time the corresponding channel in the time histogram of the triple coincidences.

When both logic signals from the other two channels (2^{nd} and 3^{rd} channels) are detected synchronously by a clock pulse the same channel, corresponding to the duration between the arrivals of the first and second pulses (expressed as a number of clock ticks), is incremented in the histograms of the double and triple coincidences.

In the special case in which no third pulse is detected during the period corresponding to the bit depth the last channel of the histogram of the triple coincidences is incremented.

As regards the portion of the algorithm dedicated to managing the extendible-type dead time and to measuring the live time, this portion is a transposition of the MAC3 analog module. This transposition has already been used in a digital system for measuring coincidences by the overlap time method (see documents [4] and [5]). It is recalled that this technique does not retain the time information.

The dead time is initiated synchronously with the start of the time measuring phase for a minimum duration which is expressed as a number of clock ticks.

According to the principle of the extendible-type dead time, every new logic signal from the three CFD modules and arriving during a dead time period extends this period by the same minimum duration (which is defined by the user).

The live time represents the actual duration of the measurement. It is measured in real time, sampling the periods outside the dead time with the clock of the FPGA.

The timing diagram of FIG. 3 provides a representation of the execution of the algorithm of FIG. 2 (which is used in one example of the present invention). It should be noted that the discrimination duration of the logic signals is also taken into account in the extension of the dead time.

It should also be noted that the dead time is managed from a synchronisation of the signals with the clock pulses, as with the management of the time measurements.

After the histograms are corrected by dividing the content of the channels by the live time measurement, the count rates of the multiple coincidences may be calculated. The values of these rates are given by the total of the content of the channels corresponding to the time region which is defined by the user.

In the case of the TDCR method the first channels corresponding to an optimum coincidence resolution time are chosen, with the aim of preventing any loss of information contained in the histograms of the double and triple coincidences.

The present invention has various industrial applications.

Indeed, in industry, many fields require measurements involving a time-to-digital converter, for example measurements in the field of time-frequencies, or measurements in the photonics field.

In particular, in the field of metrology of radioactivity and, more generally, of nuclear physics and of particles, the present invention remedies a very specific disadvantage, due to radiation detectors, namely the random nature of the arrival times of the pulses, possibly with the presence of post-pulses, the time distribution of which is difficult to characterise.

Furthermore, examples have been given of the invention in which three radiation detectors are used. But the present invention is not restricted to this case: those skilled in the art may adapt the given examples to a case in which more than three radiation detectors are used.

Those skilled in the art may even adapt these examples to the case in which only two radiation detectors are used. In the field of metrology of radioactivity, this case corresponds, for example, to the method of 4πβ-γ coincidences. This method may combine two different detectors, for example a proportional counter and a detector of the scintillator type.

In addition, a time-to-digital converter is useful in the case of the measurement of the live time of a metastable state in the decay scheme of particular radionuclides.

1. A method for measuring the count rate of coincident events between N radiation detectors operating in parallel, and associated respectively with N detection channels, where N is an integer equal to at least 2, and where each detector is able to send an electric pulse over the detection channel with which it is associated when an event occurs in this detector, in which:
the time fluctuations of the coincident events are converted into digital form, and
the extendible dead time method is used with measurement of the live time to eliminate all the other correlated events which may occur within a given detector,
characterised in that:
the time distributions of the time intervals separating the pulses are recorded, and
the count rate of the coincident events is measured using the recorded time distributions.

2. A method according to claim 1, in which the live time is measured in real time.

3. A method according to claim 1, in which the dead time is common to the N detection channels.

4. A method according to claim 1, in which:
measurement of the count rate is initiated by one of the N detection channels when an event occurs in the detector associated with it, and
when the measurement is initiated an algorithm is implemented which establishes time histograms for the multiple coincidences between the N detection channels, i.e. for the coincident events between P detectors from among the N radiation detectors, where P spans all the integers ranging from 2 to N, from the input times of the pulses in the N−1 other detection channels.

5. A method according to claim 1, in which the detectors are identical.

6. A method according to claim 5, in which N is equal to 3, the detectors are photomultipliers and the method is used to implement the triple to double coincidence ratio method.

7. A method according to claim 1, in which the detectors are not identical.

8. A method according to claim 7, in which N is equal to 2, the detectors are respectively a gamma photon detector and an electron detector, and the method is used to implement the beta-gamma coincidence method.
